(19) United States
(12) Patent Application Publication
(10) Pub. No.: US 2015/0003083 A1
(43) Pub. Date: Jan. 1, 2015

(54) FLEXIBLE PRINTED WIRING BOARD, FLEXIBLE CIRCUIT BOARD, AND ELECTRONIC APPARATUS USING THE FLEXIBLE CIRCUIT BOARD

(71) Applicant: CANON COMPONENTS, INC., Saitama (JP)

(72) Inventor: Hiroharu UEHARA, Saitama (JP)

(21) Appl. No.: 14/315,639

(22) Filed: Jun. 26, 2014

(30) Foreign Application Priority Data
Jun. 27, 2013 (JP) 2013-135259
Jun. 24, 2014 (JP) 2014-129265

(51) Int. Cl. H05K 1/02; F21K 99/00

(52) U.S. Cl. CPC H05K 1/028; H05K 1/0209; F21K 9/30
USPC 362/418; 174/254

(57) ABSTRACT

An FPC includes: a base film including a first metal sheet; a first adhesive layer laminated on one of surfaces of the base film; and a conductor pattern bonded by the first adhesive layer; wherein a plurality of planar portions held in a planar shape and bending portions to be bent provided between the planar portions are arranged in a longitudinal direction, and the conductor pattern is covered by a metal support cover film including a second metal sheet and a second adhesive layer at the planar portions and is covered by a solder resist at the bending portions.

### CROSS-REFERENCE TO RELATED APPLICATIONS

This application is based upon and claims the benefit of priority of the prior Japanese Patent Application No. 2013-135259, filed on Jun. 27, 2013, and the Japanese Patent Application No. 2014-129265, filed on Jun. 24, 2014, the entire contents of which are incorporated herein by reference.

### BACKGROUND OF THE INVENTION

1. Field of the Invention

The present invention relates to a flexible printed wiring board, a flexible circuit board, and an electronic apparatus using the flexible circuit board. Particularly, the present invention relates to a flexible printed wiring board including a base film including a metal sheet, a flexible circuit board in which electronic components are mounted on the flexible printed wiring board, and an electronic apparatus provided with the flexible circuit board.

2. Description of the Related Art

Conventionally, there is an illumination apparatus on which a solid-state light emitting element is mounted on a printed wiring board including a predetermined circuit pattern. Such an illumination apparatus provided with a flexible printed wiring board with flexibility (hereinafter, described as “FPC”) is known.

Patent Document 1 discloses a manufacturing method of the FPC, the method including: a step of forming a laminated plate by bonding a single-sided copper-clad flexible substrate to one of surfaces of a plate-like base material including a metal plate and the like; a step of forming a conductor pattern by patterning copper foil of the single-sided copper-clad flexible substrate; and a step of obtaining the FPC by cutting the laminated plate provided with the conductor pattern made of the copper foil. Grooves are formed in advance on the other surface of the plate-like base material to allow bending the FPC after a mounting step. Patent Document 1 further discloses a method of using the FPC to manufacture a light emitting module through a light emitting element mounting step and a bending step.

In a flexible printed board for mounting an LED element with a large local heat amount due to light emission, a metal substrate with high heat radiation may be used to further improve the heat resistance and heat radiation design. For example, Patent Document 2 discloses a configuration, wherein a metal support flexible substrate has a laminate structure of an adhesive layer, a supporting body, and a supporting body covering layer, and the supporting body is formed by metal foil. Patent Document 2 further discloses a manufacturing method of a metal support flexible printed wiring board for mounting LED using the metal support flexible substrate, wherein copper foil is laminated on a surface of the metal support flexible substrate, and a circuit is formed from the copper foil.

A vehicle illumination apparatus provided with an LED as a light source may be attached to a light emission surface formed in a curved shape and used. In the vehicle illumination apparatus, a flexible printed board on which the LED is mounted (particularly, LED attachment part) may be formed in a step shape along the curved shape of the light emission surface. For example, Patent Document 3 discloses a metal base FPC formed in a step shape, wherein a flexible printed board and a flexible metal base are integrated. The flexible printed board includes a copper foil pattern integrated with an insulating resin film, and the rigidity is not sufficient. Meanwhile, the metal base includes: copper foil with a thickness of a hundred and several dozen μm; and a thermally conductive insulating film integrally provided on the back surface of the copper foil. As a result, the metal base FPC is flexible and has sufficient strength that can hold a shape formed by bending (step-like shape).

There is a demand for forming a printed circuit board provided with an LED or a printed circuit board in an illumination apparatus provided with a camera module, in various shapes, such as bent plate shapes including L-shaped or U-shaped plates, as well as polygonal cylinder shapes. Patent Documents 1 to 3 disclose configurations, wherein a printed circuit board is formed in a desired shape, and a hard supporting material is used in addition to an elastic flexible wiring board to hold the formed shape. However, the configurations described in Patent Documents 1 to 3 require many members, and the increase in the number of components increases assembly man-hours. For example, the configuration disclosed in Patent Document 1 requires a plate-like base material, such as a metal plate, and a thermoplastic film material for bonding a flexible copper-clad plate to the plate-like base material and requires a fusion step of bonding them. The illumination apparatus disclosed in Patent Document 3 requires a metal base made of thick copper foil in addition to a flexible printed wiring board made of a resin film and requires a vacuuming step of bonding them. Furthermore, the size or the product design may be affected in an electronic apparatus provided with the printed circuit board.

### Patent Document 1

Japanese Laid-open Patent Publication No. 2011-249534

### Patent Document 2

Japanese Laid-open Patent Publication No. 2013-038360

### Patent Document 3

Japanese Laid-open Patent Publication No. 2012-160430

### SUMMARY OF THE INVENTION

In view of the circumstances, an object of the present invention is to provide a flexible printed wiring board with excellent heat radiation that can easily form a three-dimensional shape by bending, a flexible circuit board, and an electronic apparatus provided with the flexible circuit board.

The present invention provides a flexible printed wiring board including: a base film including a first metal sheet; a first adhesive layer laminated on one of surfaces of the base film; a conductor pattern bonded by the first adhesive layer; and a cover layer that covers the conductor pattern, wherein a plurality of planar portions held in a planar shape and bending portions to be bent provided between the planar portions are arranged in a longitudinal direction, the cover layer provided to the planar portions includes a second metal sheet and a second adhesive layer, and the cover layer provided to the bending portions includes a resin cover coat.

### BRIEF DESCRIPTION OF THE DRAWINGS

FIG. 1 is a flat-surface schematic view showing an example of a configuration of a flexible circuit board;

FIG. 2 is a sectional view of a II-II line of FIG. 1;

FIG. 3 is a sectional schematic view showing an example of a state in which the flexible circuit board is formed in a three-dimensional shape;

FIG. 4 is a flat-surface schematic view showing an additional example of the configuration of the flexible circuit board shown in FIG. 1;

FIG. 5A is a sectional schematic view showing a step of a manufacturing method of the flexible circuit board;

FIG. 5B is a sectional schematic view showing a step of the manufacturing method of the flexible circuit board;

FIG. 5C is a sectional schematic view showing a step of the manufacturing method of the flexible circuit board;

FIG. 5D is a sectional schematic view showing a step of the manufacturing method of the flexible circuit board;

FIG. 5E is a sectional schematic view showing a step of the manufacturing method of the flexible circuit board;

FIG. 5F is a sectional schematic view showing a step of the manufacturing method of the flexible circuit board;

FIG. 5G is a sectional schematic view showing a step of the manufacturing method of the flexible circuit board;

FIG. 6 is a sectional schematic view showing an example of a configuration of an illumination apparatus;

FIG. 7 is a schematic view showing a state in which the flexible circuit board is formed in a three-dimensional shape;

FIG. 8 is a schematic view showing a state of a planar shape before the flexible circuit board is formed in the three-dimensional shape;

FIG. 9 is a front-surface schematic view of a vehicle lamp;

FIG. 10 is a perspective view of an illumination apparatus;

FIG. 11 is a sectional schematic view of the illumination apparatus;

FIG. 12 is a flat-surface schematic view showing a configuration example of a flexible circuit board according to a second embodiment;

FIG. 13 is a sectional schematic view showing a configuration example of the flexible circuit board according to the second embodiment;

FIG. 14 is a sectional schematic view showing a configuration example of the flexible circuit board;

FIG. 15 is a flat-surface schematic view showing a configuration example of the flexible circuit board according to another example of the second embodiment;

FIG. 16 is a sectional schematic view showing a configuration example of the flexible circuit board according to the example of the second embodiment;

FIG. 17 is a front-surface schematic view showing a configuration example of a vehicle lamp provided with an illumination apparatus; and

FIG. 18 is a sectional schematic view showing the configuration example of the vehicle lamp provided with the illumination apparatus.

### DETAILED DESCRIPTION OF THE PREFERRED EMBODIMENTS

### First Embodiment

### <<Configurations of Flexible Printed Wiring Board (FPC) and Flexible Circuit Board>>

In a flexible circuit board 1 according to a first embodiment, electronic components 11, such as semiconductor devices and passive elements, are mounted on an FPC 2 (flexible printed wiring board: Flexible Print Circuit) for TAB (Tape Automated Bonding). The flexible circuit board 1 can hold a three-dimensional shape formed by bending the FPC 2, in a state that the electronic components 11 are mounted on the FPC 2. Alternatively, the flexible circuit board 1 is incorporated into another electronic apparatus, such as an illumination apparatus (described later), and used. In the first embodiment, a base film 21 of the FPC 2 applied to the flexible circuit board 1 has a function of heat radiation of the mounted electronic components 11 and the like.

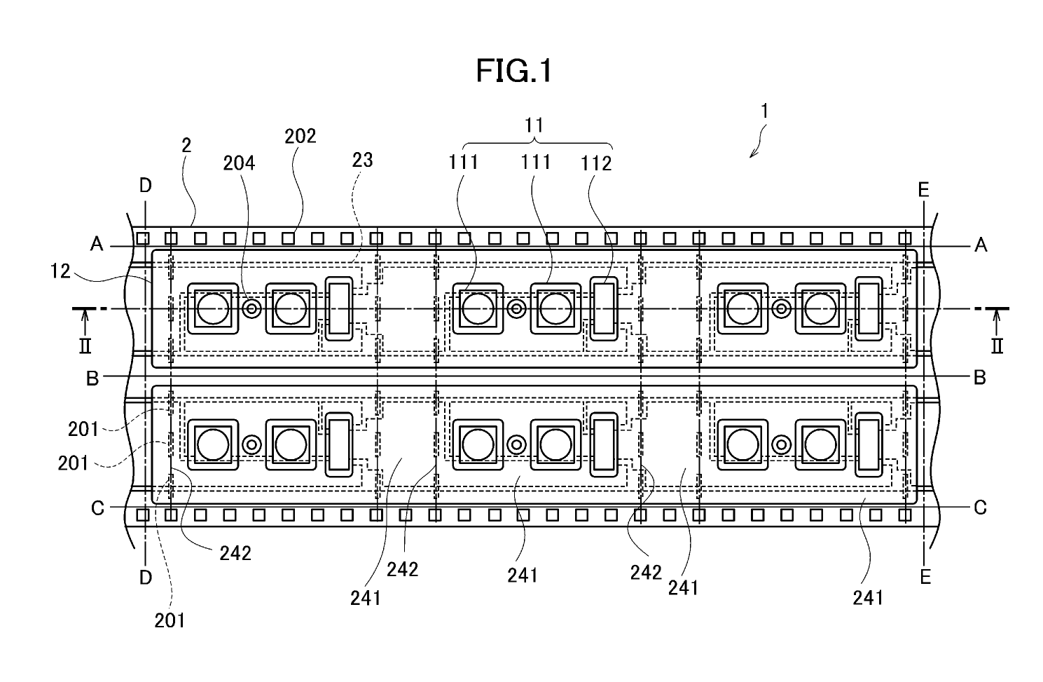

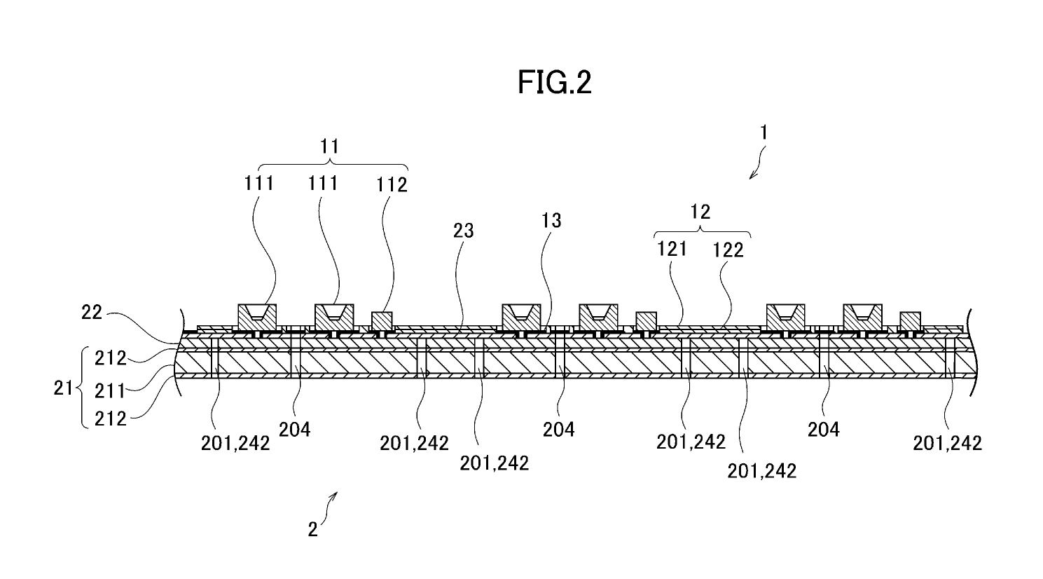

Configurations of the FPC 2 and the flexible circuit board 1 provided with the FPC 2 will be described with reference to FIGS. 1 and 2. FIG. 1 is a flat-surface schematic view showing an example of the configuration of the flexible circuit board 1 provided with the FPC 2. FIG. 2 is a sectional schematic view showing an example of the configuration of the flexible circuit board 1 and is a sectional view of a II-II line of FIG. 1. FIGS. 1 and 2 show a state of a planar shape before the flexible circuit board 1 is formed in a three-dimensional shape. FIG. 1 shows a state just after manufacturing by a roll-to-roll process. After the manufacturing, the flexible circuit board 1 is cut at cutting lines A-A, B-B, C-C, D-D, and E-E and separated into pieces (fragments).

The flexible circuit board 1 includes, for example: the FPC 2 for TAB; the electronic components 11, such as semiconductor devices and passive elements, mounted on a surface of the FPC 2; and a cover film 12 as an example of a cover layer bonded to one of the surfaces of the FPC 2.

The FPC 2 includes: the base film 21, a first adhesive layer 22 laminated and formed on one of the surfaces of the base film 21; and a conductor pattern 23 bonded by the first adhesive layer 22. Therefore, the FPC 2 has a three-layer laminate structure of the base film 21, the first adhesive layer 22, and the conductor pattern 23.

The base film 21 includes a first metal sheet 211 and insulating films 212 covering both surfaces of the first metal sheet 211. In addition to electrical insulation, the insulating films 212 are designed to facilitate adhesion to the first adhesive layer 22 and to protect the first metal sheet from chemicals in the formation of the conductor pattern 23. Sprocket holes 202 for TAB are formed on the base film 21, and slit holes 201 (described later) for forming the FPC 2 in a three-dimensional shape are formed at bending positions 242 (described later) of the base film 21. Fixation holes 204 for inserting screws or the like for fixation are also formed on the base film 21. Additionally, device holes or the like for mounting semiconductor devices or passive/active elements as examples of the electronic components 11 may be formed on the base film 21. The sprocket holes 202, the slit holes 201, the fixation holes 204, and the device holes are openings (through-holes) penetrating the base film 21 in the thickness direction. In this way, the base film 21 is provided with openings successively penetrating the first metal sheet 211 and the two insulating films 212 covering both surfaces of the first metal sheet 211 in the thickness direction.

The first metal sheet 211 has rigidity that can hold the formed three-dimensional shape (bent three-dimensional shape) when plastic deformation is used to bend and form the three-dimensional shape. For example, the first metal sheet 211 can be aluminum foil of about 80 μm in thickness. The thickness of the aluminum foil as the first metal sheet 211 is not limited to 80 μm. It is only necessary that the aluminum foil as the first metal sheet 211 has a thickness with rigidity that can hold the bent three-dimensional shape when the FPC 2 is bent into the three-dimensional shape. It is preferable that the thickness of the aluminum foil for holding the bent three-dimensional shape is 10 μm or more, and it is further preferable that the thickness is 30 μm or more.

However, the preferable thickness for holding the three-dimensional shape also depends on conditions, such as the dimension and the shape of the flexible circuit board 1 and the installation positions of the mounted electronic components 11. Therefore, the thickness of the aluminum foil is appropriately set according to the conditions. For example, when the roll-to-roll process is applied to manufacture the flexible circuit board 1, it is preferable that the thickness of the aluminum foil is in a range of about 20 to 150 μm. When a panel processing method (method of processing the FPC 2 for each panel in a predetermined size) is applied to manufacture the flexible circuit board 1, it is preferable that the thickness of the aluminum foil as the first metal sheet 211 is in a range of 30 to 400 μm.

In this way, the first metal sheet 211 has a function of a strength member for holding the three-dimensional shape formed by bending the FPC 2 (flexible circuit board 1). The first metal sheet 211 also has a function of radiating the heat of the electronic components 11 mounted on the FPC 2 and a function of an electromagnetic shield. Therefore, the thermal conductivity of the first metal sheet 211 is higher than a sheet made of a resin material, and the first metal sheet 211 has a function of excellent heat radiation. Since the first metal sheet 211 blocks electromagnetic waves, emission of noise to the outside by the conductor pattern or the electronic components 11 as well as influence of noise from the outside can be prevented or suppressed.

Organic insulating films made of a resin material are applied as the insulating films 212. For example, a polyimide resin or a polyamidoimide resin with excellent heat resistance and chemical resistance is preferable to protect the first metal sheet 211 from scratches and corrosion. In the first embodiment, polyimide resin films (organic insulating films) of about 4 μm in thickness can be applied. The thin organic insulating films facilitate transmitting the heat generated by the electronic components 11 mounted on the FPC 2 to the first metal sheet 211 through the insulating films 212 and facilitate radiating the heat of the first metal sheet 211 to the outside of the flexible circuit board 1. Therefore, the effect of cooling the electronic components 11 can be increased.

The first adhesive layer 22 can be, for example, a product name “Adhesive Tape for TAB #8200” of about 12 μB in thickness manufactured by Toray Industries, Inc. The adhesive tape for TAP is a sheet based on an epoxy resin. The electrical insulation is high, and the thermal conductivity is about 1 W/(m·K). To improve the thermal conductivity, it is preferable that the first adhesive layer 22 is as thin as possible from the viewpoint of thermal conduction.

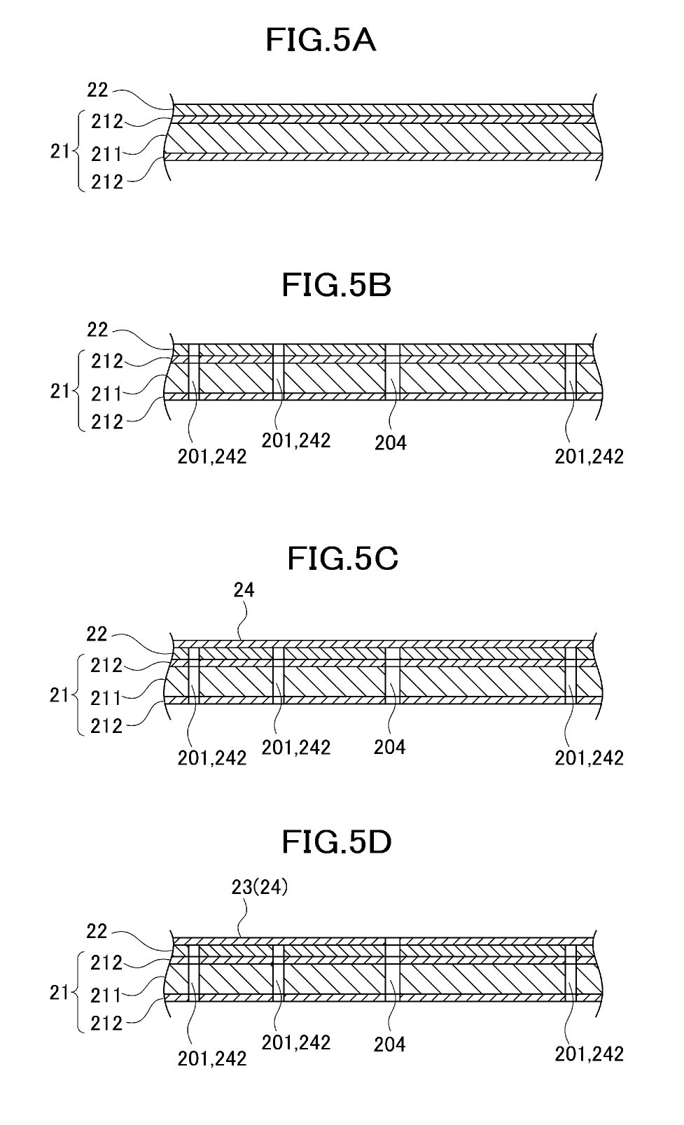

The conductor pattern 23 is formed by conductor foil 24 (see FIG. 5C). A laminator of a thermo-compression type is used to bond the conductor foil 24 on the surface of one of the insulating films 212 of the base film 21, through the first adhesive layer 22. The conductor foil 24 can be, for example, electrolytic copper foil (standardized product) of 35 μm in thickness. The specific configuration of the conductor pattern 23 is appropriately set according to the usage, the function, and the like of the flexible circuit board 1 and is not limited.

Part of the conductor pattern 23 is covered by the cover film 12 as an example of the cover layer. The cover film 12 can be, for example, a film with a laminate structure of an aramid resin film 121 of about 5 μm in thickness and a cover adhesive layer 122 made of an epoxy resin of about 30 μm in thickness. A plating layer 13 is formed on part of the conductor pattern 23 that is exposed without being covered by the cover film 12.

The electronic components 11 are appropriately mounted according to the usage and the like of the flexible circuit board 1 (FPC 2), and the types and the like are not limited. The first embodiment illustrates an example in which the flexible circuit board 1 is applied to an illumination apparatus. Therefore, LEDs 111 as light emitting elements and constant-current regulators 112 that control current applied to the LEDs 111 are mounted as the electronic components 11 in the illustrated example. FIGS. 1 and 2 illustrate an example in which two LEDs 111 and one constant-current regulator 112 are connected and arranged in series.

The slit holes 201 formed at the bending positions 242 will be described. The bending positions 242 denote positions for bending the FPC 2 (flexible circuit board 1) in mountain folds and valley folds. The slit holes 201 are openings penetrating the base film 21 in the thickness direction and are formed to bend the FPC 2 (flexible circuit board 1) in a desired three-dimensional shape. For example, as shown in FIG. 1, the slit holes 201 have shapes elongated in the short direction of the FPC 2. A plurality of slit holes 201 are arranged and formed in series like perforations at the bending positions 242. In other words, the bending positions 242 are specified by rows of slit holes 201. FIG. 1 shows the bending positions 242 by alternate short and long dash lines. Although FIG. 1 shows a configuration in which three slit holes 201 are formed in series, the number of slit holes 201 is not limited. Although FIG. 1 shows a configuration in which the slit holes 201 are formed in an elongated shape, the shape of the slit holes 201 is not limited to this. For example, the slit holes 201 may be formed in a round or polygonal shape, and a plurality of slit holes 201 may be arranged in series like perforations. The width of the slit holes 201 is appropriately set according to the thickness or the like of the aluminum foil that is the first metal sheet 211. For example, it is preferable that the width of the slit holes 201 is 0.7 mm or more. Parts other than the bending positions 242, such as parts between the bending positions 242, serve as planar portions 241 that hold a planar shape without being bent. Therefore, in other words, the bending positions 242 are provided at boundaries between the planar portions 241.

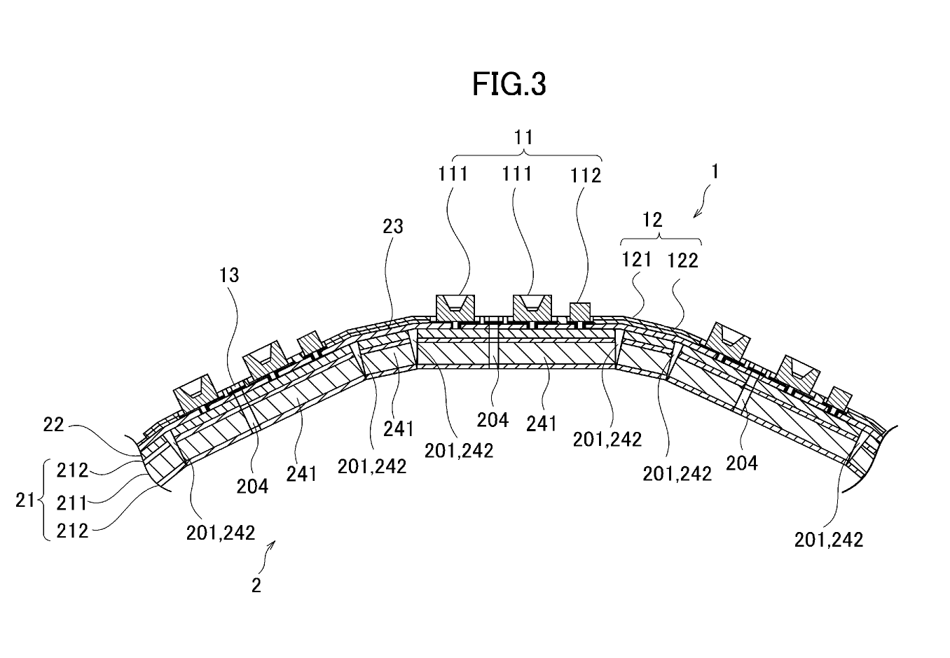

FIG. 3 is a sectional schematic view showing an example of a state in which the FPC 2 (flexible circuit board 1) is bent in a three-dimensional shape. Since the rows of slit holes 201 are formed like perforations, the rigidity of the bending positions 242 is lower than the other parts. Therefore, the FPC 2 can be easily bent (plastic deformation is easy) at areas provided with the slit holes 201 like perforations. Therefore, the formation of the rows of slit holes 201 like perforations on the bending positions 242 as shown in FIG. 3 facilitates forming the FPC 2 in a desired three-dimensional shape. Obviously, the shape of the slit holes 201 is not limited to the shape of long and short holes, and rows of round holes may be formed like perforations. The bending positions 242 are appropriately linearly set according to a desired three-dimensional shape of the FPC 2, and the shape is not particularly limited.

In this way, the configuration in which the plurality of slit holes 201 are provided like perforations at the bending positions 242 facilitates the formation of the three-dimensional shape of the flexible circuit board 1 (FPC 2). Particularly, there is an effect of improving the accuracy of the bending shape and the bending positions 242 of the flexible circuit board 1. When aluminum foil is applied as the first metal sheet 211, the effect is prominent if the thickness of the first metal sheet 211 is 50 μm or more.

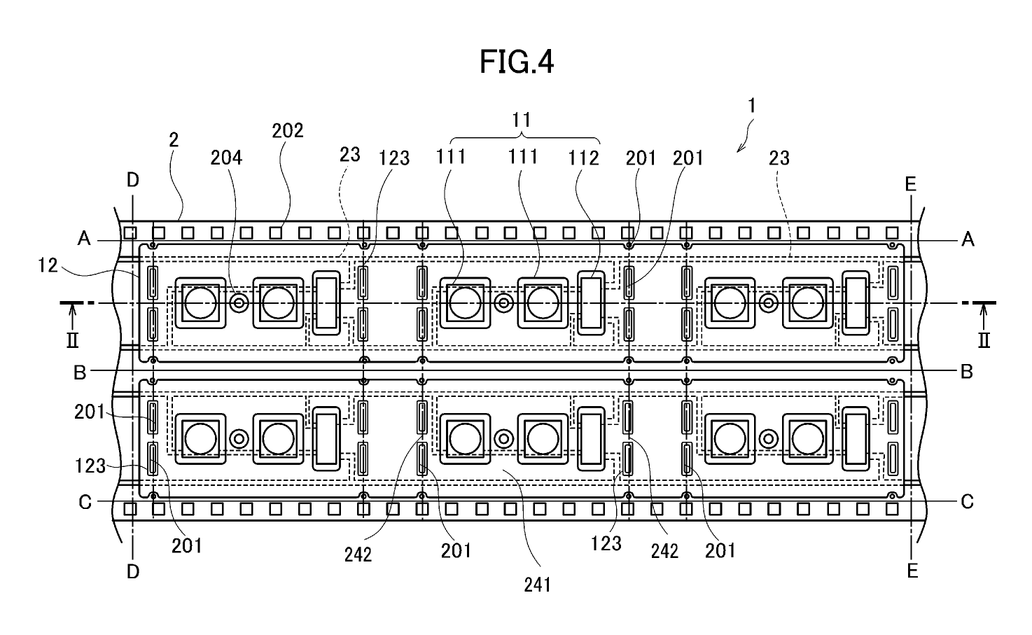

An additional example of the flexible circuit board 1 (FPC 2) will be described with reference to FIG. 4. FIG. 4 is a flat-surface schematic view showing the additional example of the flexible circuit board 1. Configurations common to FIG. 1 are provided with the same reference numerals, and the description will not be repeated. In the flexible circuit board 1 (FPC 2) according to the additional example shown in FIG. 4, the slit holes 201 provided at the bending positions 242 are not provided at positions overlapping the conductor pattern 23 in plan view. This is to prevent or suppress damage of the conductor pattern 23 caused by the deformation by bending the flexible circuit board 1. According to the configuration, the damage to the conductor pattern 23 in bending can be significantly reduced compared to the configuration in which the slit holes 201 are provided at positions overlapping the conductor pattern 23 in plan view.

In the cover films 12, openings 123 greater than the corresponding slit holes 201 are formed on the cover film 12 at positions corresponding to the slit holes 201. More specifically, peripheries of the slit holes 201 are exposed from the openings 123 without being covered by the cover film 12. The configuration can prevent the adhesion of the cover adhesive layer 122 of the cover film 12 by coming around into the slit holes 201. Furthermore, the area of the cover film 12 at the bending positions 242 (here, areas including the surrounding of the slit holes 201) of the flexible circuit board 1 is small. Therefore, the bending deformation of the flexible circuit board 1 is mainly governed by the plastic deformation of the base film 21, and the influence of the elastic force and the like of the cover film 12 is reduced. Therefore, the flexible circuit board 1 is easily held at the bent shape.

The effect of the configuration according to the additional example can also be obtained by a configuration in which the slit holes 201 are formed as round holes and arranged like perforations. The configuration according to the additional example can also attain the effect even if the cover film 12 is replaced by a solder resist that is an insulating protective film including an organic material.

### <<Manufacturing Method of Flexible Circuit Board>>

A manufacturing method of the flexible circuit board 1 will be described with reference to FIGS. 5A to 5G. FIGS. 5A to 5G are sectional schematic views showing steps of the manufacturing method of the flexible circuit board 1. Although FIGS. 5A to 5G illustrate steps of the manufacturing method of the flexible circuit board 1 shown in FIG. 1, the flexible circuit board 1 according to the additional example shown in FIG. 4 is also manufactured in the same steps as the steps shown in FIGS. 5A to 5G.

In the first embodiment, the roll-to-roll process can be applied as the manufacturing method of the flexible circuit board 1. In the roll-to-roll process, the elongated base film 21 wound around a roll is used as a starting material, and the base film 21 is rolled up to another roll to continuously manufacture the flexible circuit board 1.

As shown in FIG. 5A, the first adhesive layer 22 is laminated on one of the surfaces of the base film 21 including the first metal sheet 211 and the two insulating films 212. Aluminum foil of about 80 μm in thickness is applied as the first metal sheet 211. The insulating films 212 can be, for example, polyimide resin films (organic insulating films) of about 4 μm in thickness. It is preferable that the thickness of the aluminum foil as the first metal sheet 211 is in a range of 20 to 150 μm to manufacture the flexible circuit board 1 by the roll-to-roll process. As described, the product name “Adhesive for TAB #8200”can be applied as the first adhesive layer 22. In this case, the first adhesive layer 22 is laminated on the surface of the insulating film 212 of the base film 21.

As shown in FIG. 5B, openings (through-holes), such as the sprocket holes 202, the slit holes 201, and the fixation holes 204, are formed on the base film 21 on which the first adhesive layer 22 is laminated. A punching process using a press die can be applied to form the openings. The sprocket holes 202, the slit holes 201, and the fixation holes 204 are openings that successively penetrate the base film 21 and the first adhesive layer 22. It is preferable to arrange the slit holes 201 in series like perforations on the bending positions 242. Although the width of the slit holes 201 is not particularly limited, a width of 0.7 μmm or more is suitable, for example. Particularly, if the width is 0.7 μmm or more, die cutting can be easily performed as in the processing of other holes (device holes and sprocket holes 202), and the productivity is excellent.

As shown in FIG. 5C, the conductor foil 24 is heated, pressurized, and bonded to the surface of the first adhesive layer 22. In the first embodiment, the conductor foil 24 can be commercially available electrolytic copper foil of 35 μm in thickness. As described, the sprocket holes 202 and the slit holes 201 are formed when the first adhesive layer 22 is laminated on the base film 21 in the first embodiment. Then, the conductor foil 24 is bonded to the surface of the first adhesive layer 22.

As shown in FIG. 5D, the conductor pattern 23 is formed from the conductor foil 24. Well-known photoetching (photolithography) can be applied to form the conductor pattern 23. In the formation of the conductor pattern 23, the part exposed from the slit holes 201 of the conductor foil 24 is coated with an etching resist called a backing agent to avoid etching the exposed part.

As shown in FIG. 5E, the cover film 12 as an example of the cover layer that protects the conductor pattern 23 is bonded. The cover film 12 can be, for example, a film with a laminate structure of the aramid resin film 121 of about 5 μm in thickness and the cover adhesive layer 122 made of an epoxy resin of about 30 μm in thickness. The cover film 12 is formed in advance in an outer shape according to the completed flexible circuit board 1, and the openings (through-holes) are formed at positions equivalent to component terminals and the like for connecting the electronic components 11. After processing of the outer shape and the openings, the cover film 12 is bonded to cover the first adhesive layer 22 and the conductor pattern 23 and thermally compressed and attached.

As shown in FIG. 5F, the plating layer 13 is formed on the part not covered by the cover film 12 in the conductor pattern 23. The plating layer 13 can have a laminate structure of a nickel-plating layer 131 as a basis and a gold-plating layer 132 covering the nickel-plating layer 131. Through the steps, the FPC 2 provided with the cover film 12 is manufactured.

As shown in FIG. 5G, the electronic components 11 are mounted on the FPC 2 provided with the cover film 12. Reflow soldering for printing a solder paste on component terminals included in the conductor pattern 23 to mount the components can be applied to mount the electronic components 11, for example. The flexible circuit board 1 provided with the electronic components 11 is cut at the cutting lines A-A, B-B, C-C, D-D, and E-E shown in FIG. 1 and separated into individual pieces (fragments). Through the steps, the flexible circuit board 1 is manufactured.

The plastic deformation of the first metal sheet 211 can be used to form the FPC 2 (flexible circuit board 1) in a three-dimensional shape. In this case, the configuration of forming the rows of slit holes 201 like perforations at the bending positions 242 facilitates forming the FPC 2 in a designed three-dimensional shape. The FPC 2 can be held in the formed three-dimensional shape based on the rigidity of the first metal sheet 211. Therefore, the FPC 2 is processed into the flexible circuit board 1 in which the three-dimensional shape is formed by the bending positions 242, which are bent in mountain folds or valley folds, and the planar portions 241, which are provided with LEDs at the center and placed between two bending positions 242.

In this way, according to the first embodiment (including the additional example), a flexible copper-clad plate, which includes laminated and bonded copper foil and resin base film, and a thermoplastic film, which is used as an insulating resin layer that bonds a plate-like base material and the flexible copper-clad plate, as in the conventional techniques are not necessary. A step of bonding and laminating them is not necessary, either. Therefore, an increase in the materials or steps to manufacture the FPC 2 (flexible circuit board 1) can be prevented or suppressed.

According to the first embodiment, the FPC 2 (flexible circuit board 1) can be easily formed in a desired three-dimensional shape by forming the slit holes 201 at the bending positions 242 of the FPC 2. Since the slit holes 201 can be formed at the same time in the same step as the formation of the sprocket holes 202 and the like, the number of steps is not increased.

### Electronic Apparatus

### First Example

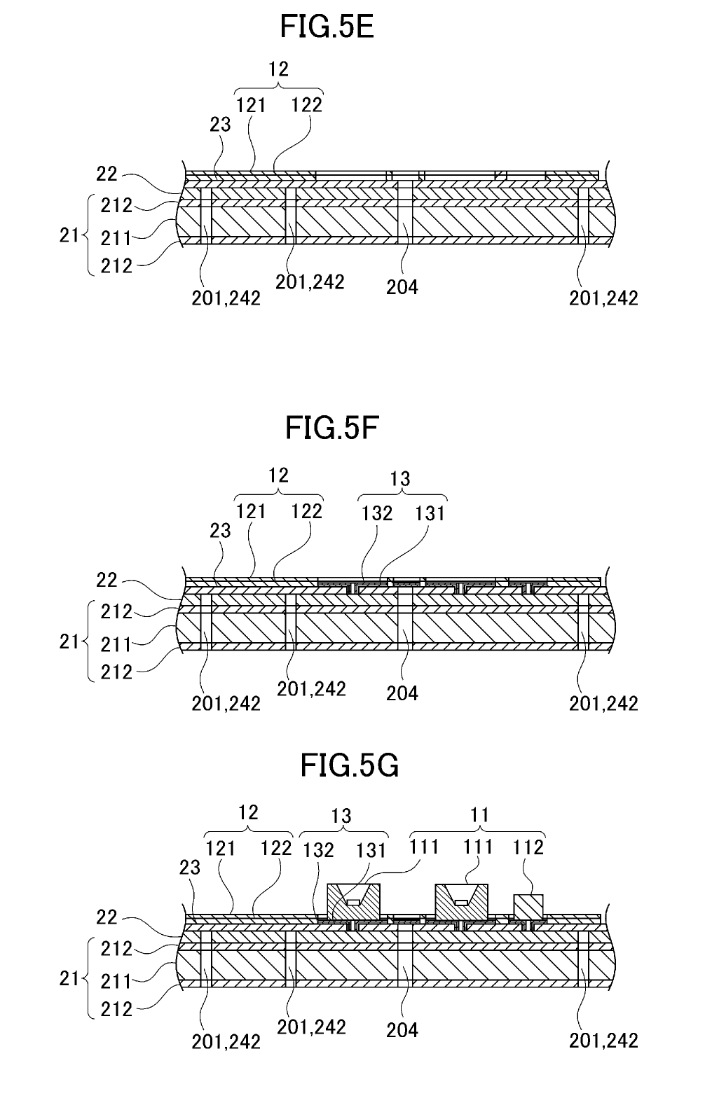

A first example of an electronic apparatus provided with the flexible circuit board 1 will be described. An illumination apparatus 5 will be illustrated in the first example of the electronic apparatus. FIG. 6 is a sectional schematic view showing a configuration of the illumination apparatus 5 in the first example of the electronic apparatus. The illumination apparatus 5 illustrated in this example includes a plurality of LEDs 111 as light emitting elements and can generate diffusive light. The illumination apparatus 5 includes the flexible circuit board 1 and a supporting member 51 on which the flexible circuit board 1 is attached. Although the illumination apparatus 5 can further include members such as a housing, this will not be illustrated and described here.

Rows of slit holes 201 are formed at the bending positions 242 of the FPC 2 (flexible circuit board 1), in series in the short direction like perforations. The rows of slit holes 201 are formed in the longitudinal direction at predetermined intervals. The plurality of (two in the example of FIG. 6) LEDs 111 and the constant-current regulator 112 that adjusts current applied to the LEDs 111 are mounted as the electronic components 11 between the rows of the slit holes 201. A power feeding cable 53 for receiving electric power from an external power supply is further connected to the flexible circuit board 1. For the convenience of the description, an area between the rows of slit holes 201 like perforations where the plurality of LEDs 111 and the constant-current regulator 112 are mounted will be described as one “block”.

A supporting surface 511 (surface on which the flexible circuit board 1 is attached) of the supporting member 51 is formed in a predetermined three-dimensional shape. In the present embodiment, the supporting surface 511 is formed by a plurality of flat surfaces with different normal directions and has a convex shape, projecting in a curved shape as a whole. The FPC 2 of the flexible circuit board 1 is bent at the bending positions 242 where the rows of slit holes 201 like perforations are formed and is formed in a three-dimensional shape along the supporting surface 511 of the supporting member 51. The flexible circuit board 1 in the three-dimensional shape is fixed to the supporting member 51. For example, one block of the flexible circuit board 1 is positioned on one flat surface included in the supporting surface 511 of the supporting member 51. According to the configuration, the directions of the optical axes of the LEDs 111 mounted on the flexible circuit board 1 can be different block by block, and the light generated by the LEDs 111 can be expanded. In this way, the FPC 2 of the flexible circuit board 1 is bent to make the directions of the optical axes of the plurality of LEDs ill different in the present embodiment. As a result, an illumination apparatus 5 that emits light in a desired direction can be manufactured. The positions of the rows of slit holes 201 are set in advance according to the configuration of the supporting surface 511 of the supporting member 51.

The FPC 2 of the flexible circuit board 1 is fixed to the supporting member 51 by screws 52 near the LEDs 111 of each block. For example, in a configuration in which two LEDs 111 are mounted on one block, the fixation hole 204 is formed between the two LEDs 111, and the screw 52 for fixation is inserted to the fixation hole 204 to fix each block to the supporting surface 511 of the supporting member 51. According to the configuration, the FPC 2 touches the supporting member 51 near the LEDs 111 of each block. Therefore, the heat generated by the LEDs 111 is easily transmitted to the supporting member 51. In a configuration of using a metal screw 52, the heat generated by the LEDs 111 can also be transmitted to the supporting member 51 through the screw 52. Therefore, the effect of cooling the LEDs 111 can be increased.

The method of fixing the FPC 2 of the flexible circuit board 1 to the supporting member 51 is not limited to the fixation by the screws 52. For example, the FPC 2 may be bonded to the supporting member 51 by an adhesive with high thermal conductivity near the LEDs 111 of each block. Even in such a configuration, the heat generated by the LEDs 111 can be easily transmitted to the supporting member 51.

### Electronic Apparatus

### Second Example

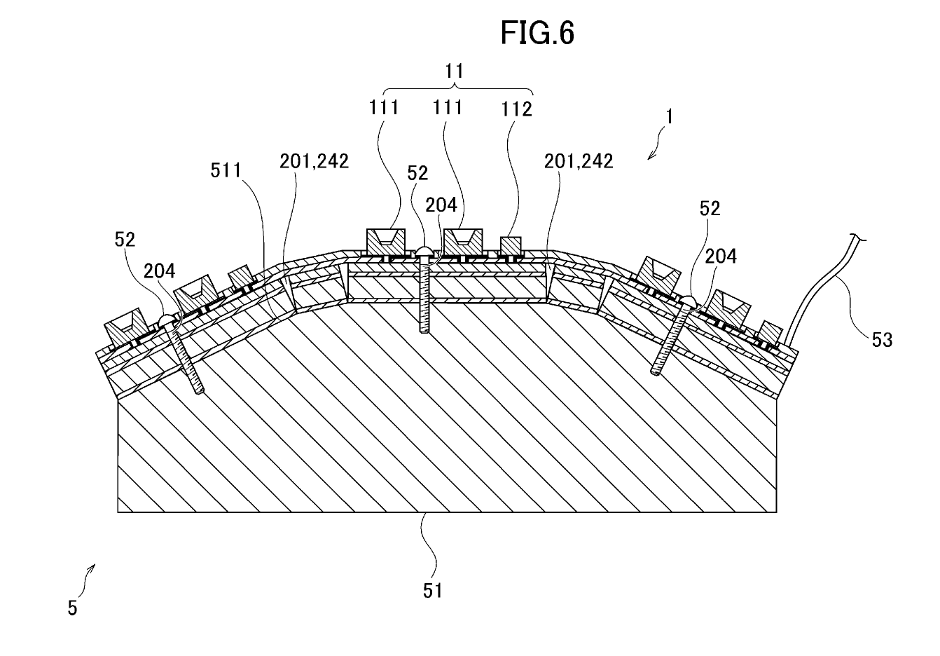

A second example of the electronic apparatus provided with the flexible circuit board 1 will be described. The second example is an example of forming the flexible circuit board 1 in a three-dimensional shape to cause the FPC 2 to function as a housing of the electronic apparatus. An imaging apparatus 6 (digital camera) incorporated into a capsule endoscope will be illustrated in the second example of the electronic apparatus. FIG. 7 is a perspective view showing an example of a configuration of the imaging apparatus 6. As shown in FIG. 7, the FPC 2 (flexible circuit board 1) is formed in a bottomed square cylinder shape as an example of the three-dimensional shape. In FIG. 7, the near side is an open side of the square cylinder, and the far side is a bottom side of the square cylinder. Desired electronic components 11, such as a camera module 61 and LEDs 111 as light emitting elements, are disposed inside of the square cylinder. According to the configuration, the FPC 2 functions as a housing of the imaging apparatus 6. The electronic components 11 are supported by the FPC 2 as a housing.

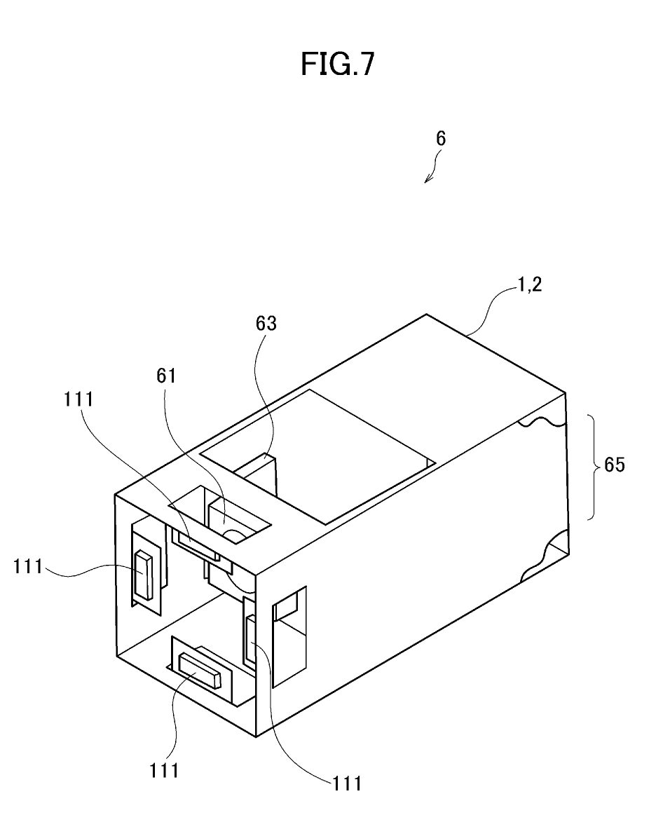

FIG. 8 is a flat-surface schematic view showing a state before the FPC 2 (flexible circuit board 1) is formed into the three-dimensional housing. As shown in FIG. 8, the FPC 2 before bending has a configuration like a developed view of a bottomed square cylinder. Rows of slit holes 201 like perforations are formed at the bending positions 242 of the FPC 2. The configuration of forming the rows of slit holes 201 like perforations at the bending positions 242 facilitates bending the flexible circuit board 1 in a bottomed square cylinder shape. In the present embodiment, the flexible circuit board 1 is bent in valley folds as seen from the side where the electronic components 11 are mounted.

The camera module 61, a control IC 62, an image data processing IC 63, and an interface IC 64 are mounted as the electronic components 11 in areas corresponding to inner surfaces of four side surfaces of the square cylinder. The LEDs 111 are mounted in areas corresponding to the inner surfaces of the four side surfaces of the square cylinder. A print contact portion 65 is formed in an area corresponding to one of the four side surfaces of the square cylinder.

The camera module 61 includes a lens and a CCD unit. The control IC 62 controls the camera module 61. The image data processing IC 63 generates transmission data to be transmitted to the outside of the imaging apparatus 6 from image data generated by the camera module 61. The interface IC 64 controls transmission and reception of signals and data between the imaging apparatus 6 and external devices. The print contact portion 65 is a portion for connecting a signal line for transmission and reception of signals between the imaging apparatus 6 and the outside and for connecting the power feeding cable 53 for receiving electric power. Although the flexible circuit board 1 may be further provided with elements for forming the imaging apparatus 6, such as a capacitor and a resistance, this will not be illustrated and described here.

Three sides of the camera module 61 in plan view are surrounded by a U-shaped through-hole 203, and the remaining side (open side of square cylinder) is surrounded by the bending positions 242 (row of slit holes 201). The part where the three sides are surrounded by the U-shaped through-hole 203 is bent upright at the bending positions 242. As a result, the optical axes of the lens and the CCD unit of the camera module 61 can face the open side of the square cylinder and can be parallel to the axis lie of the square cylinder. As in the camera module 61, three sides of the LED 111 in plan view are also surrounded by the U-shaped through-hole 203, and the remaining side is surrounded by the bending positions 242 (row of slit holes 201). The part surrounded by the U-shaped through-hole 203 is bent upright at the bending positions 242, and the light generated by the LED 111 can be emitted to the object. According to the configuration, the electronic components 11, such as the camera module 61 and the LEDs 111, can be disposed at predetermined positions by forming the rows of the slit holes 201 at the bending positions 242 of the FPC 2 and bending the FPC 2 upright at the bending positions 242. Therefore, according to the configuration, necessary electronic components 11 can be easily disposed.

In the present embodiment, the camera module 61, the LEDs 111, and the like are mounted on the FPC 2. Then, the area where the camera module 61 is mounted and the areas where the LEDs 111 are mounted are bent upright. Subsequently, the flexible circuit board 1 is bent at the bending positions 242 where the rows of the slit holes 201 are formed, and the flexible circuit board 1 is formed into a housing in a square cylinder shape in which the bottom surface is blocked. According to the configuration, the FPC 2 functions as a housing of the imaging apparatus 6 to support the electronic components 11 such as the camera module 61 and the LEDs 111. The bent FPC 2 can adjust and fix the optical axis direction of the lens and the emission direction of the LED. The mounting surface of the FPC 2 (surface on which the electronic components 11 are mounted) is bent to be positioned on the inner side of the square cylinder. According to the configuration, the electronic components 11 mounted on the FPC 2 are surrounded by the first metal sheet 211 of the base film 21. Therefore, the noise generated by the electronic components 11 mounted on the FPC 2 can be blocked, and the influence of noise from the outside (for example, influence of EMI from a surrounding high frequency circuit) can be prevented or reduced. The U-shaped through-holes 203 surrounding the three sides of the camera module 61 and the LEDs 111 are formed at the same time in the step of forming the sprocket holes 202 and the slit holes 201 on the base film 21.

As described, according to the example, the FPC 2 (flexible circuit board 1) is formed in a three-dimensional shape, and the FPC 2 can function as a housing of an electronic apparatus (imaging apparatus 6). According to the configuration, the heat generated by the electronic components 11, such as the camera module 61 and the LEDs 111, can be easily radiated through the first metal sheet 211 of the base film 21. In this case, a heat sink or the like may be attached to the FPC 2.

### Electronic Apparatus

### Third Example

A third example of the electronic apparatus provided with the flexible circuit board 1 will be described. The third example is an example of determining the directions of the optical axes of the LEDs 111 (light emitting elements) based on the bent shape in a configuration in which plastic deformation is used to bend the first metal sheet 211. In recent years, some headlamps (vehicle lamps) of four-wheeled cars include illumination apparatuses called DRL (Daytime Running Lamp) that are always turned on to alert pedestrians and oncoming vehicles (see Japanese Laid-open Patent Publication No. 2012-48896). The third example illustrates the DRL of the headlamp of the four-wheeled car as an example of applying the flexible circuit board 1.

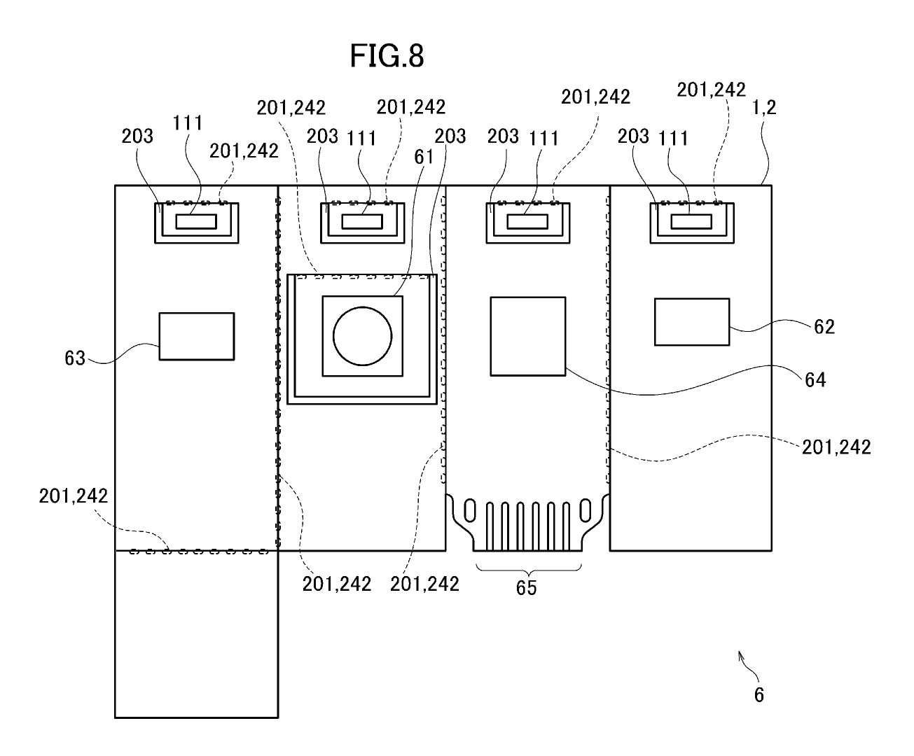

FIG. 9 is a front-surface schematic view of a left and front vehicle lamp 7 (headlamp) used for a four-wheeled car including the DRL. The vehicle lamp 7 includes a front surface lens 71, a housing 72, a first illumination apparatus 73, a second illumination apparatus 74, and a third illumination apparatus 75. The flexible circuit board 1 according to the present embodiment is applied to the third illumination apparatus 75. The front surface lens 71 is provided on the front side of the housing 72, and the housing 72 and the front surface lens 71 form a housing chamber. The first illumination apparatus 73, the second illumination apparatus 74, and the third illumination apparatus 75 are provided inside of the housing chamber.

The first illumination apparatus 73 forms a low beam. The second illumination apparatus 74 forms a high beam. The third illumination apparatus 75 has a function of the DRL. The front surface lens 71 has a function of a lens that emits forward the light generated by the first illumination apparatus 73, the second illumination apparatus 74, and the third illumination apparatus 75. The front surface lens 71 also has a function of a cover that protects the first illumination apparatus 73, the second illumination apparatus 74, and the third illumination apparatus 75. In the present embodiment, the front surface lens 71 is formed not in a flat shape, but in a bent curved shape. Each of the first illumination apparatus 73 and the second illumination apparatus 74 includes a halogen lamp and a reflector surrounding the halogen lamp. Conventionally well-known configurations can be applied to the front surface lens 71, the housing 72, the first illumination apparatus 73, and the second illumination apparatus 74. Therefore, the description will be skipped.

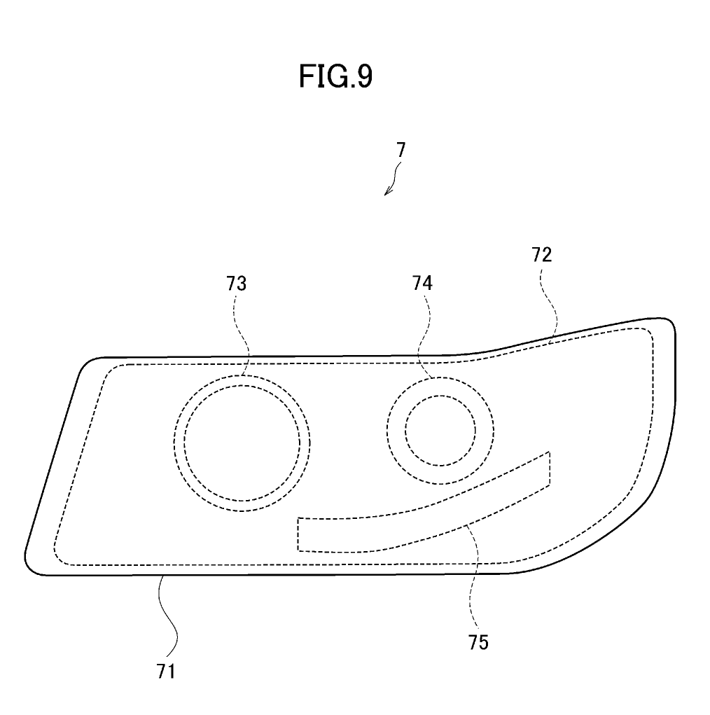

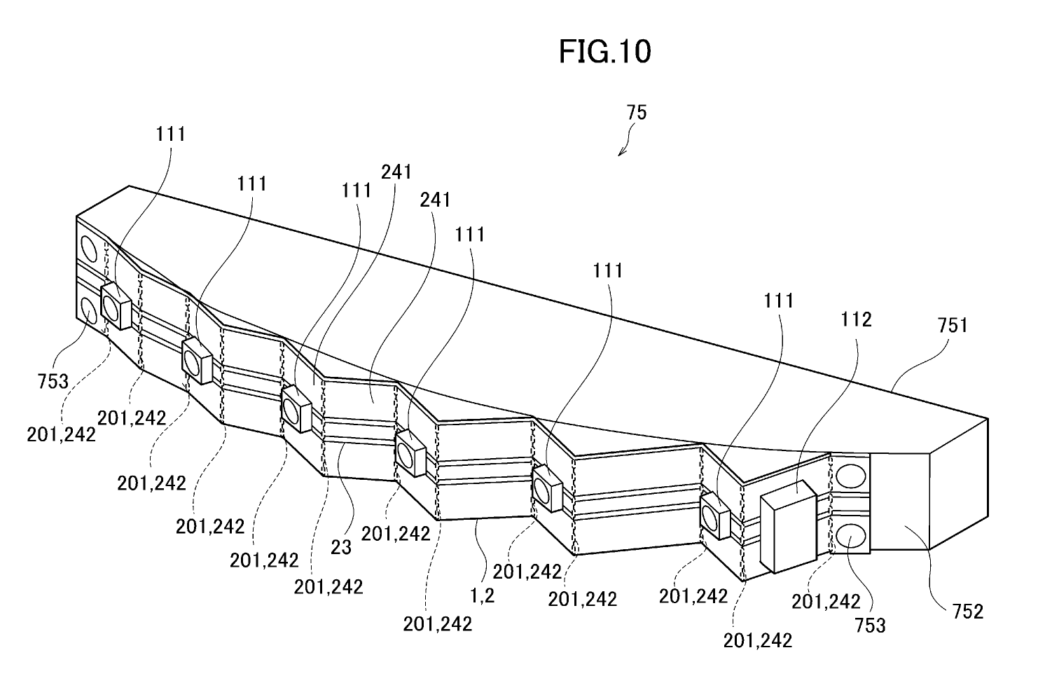

FIG. 10 is a schematic perspective view of a configuration of the third illumination apparatus 75. FIG. 11 is a sectional schematic view showing a configuration of the third illumination apparatus 75 and a relationship between the flexible circuit board 1 (FPC 2) and the front surface lens 71. The third illumination apparatus 75 includes the flexible circuit board 1 and a supporting member 751 that supports the flexible circuit board 1. The flexible circuit board 1 includes: the FPC 2; and the constant-current regulator 112 and the plurality of LEDs 111 as the electronic components 11 mounted on the FPC 2. The flexible circuit board 1 is attached to a supporting surface 752 of the supporting member 751 by attachment mechanisms such as screws 753 or the like. The FPC 2 used for the flexible circuit board 1 is formed in a band shape in front view. Rows of the slit holes 201 are formed at the bending positions 242 of the FPC 2. A plurality of bending positions 242 (rows of slit holes 201) are formed in the longitudinal direction at predetermined intervals. The rows of slit holes 201 formed at the bending positions 242 are arranged in series like perforations in a direction perpendicular to the longitudinal direction of the FPC 2. The FPC 2 is alternately bent in mountain folds and valley folds at the rows of slit holes 201 (i.e. the plurality of bending positions 242). Planar shapes are formed between the rows of slit holes 201. The parts formed in the planar shapes will be described as planar portions 241. In this way, the plurality of planar portions 241 are arranged on the FPC 2 in the longitudinal direction, and the bending positions 242 are set at boundaries between the planar portions 241. Mountain folds and valley folds are repeated in the longitudinal direction, and the FPC 2 is formed in a step shape as a whole. The plurality of planar portions 241 are arranged in series in the longitudinal direction.

As shown in FIG. 11, the FPC 2 is formed in a shape equal to or similar to the shape of the inner surface of the front surface lens 71 as a whole. Therefore, if the inner surface of the front surface lens 71 is formed in a curved surface, the FPC 2 is also formed in a curved surface equal to or similar to the curved surface of the front surface lens 71 as a whole.

One LED 111 is mounted on every other planar portion 241. The distances between the LEDs 111 mounted on every other planar portion 241 and the front surface lens 71 are all the same. Optical axes L of the LEDs 111 mounted on every other planar portion 241 are all parallel. To make the optical axes L of the LEDs 111 parallel, the normal lines of the planar portions 241 provided with the LEDs 111 are all parallel. It is preferable to use a surface-mount LED as the LED 111. To realize the configuration, the distances (in other words, distances of the planar portions 241 in the longitudinal direction) between the bending positions 242 (rows of slit holes 201) and the bending angles of the FPC 2 at the bending position 242 may not be equal. The distances between the bending positions 242 (rows of slit holes 201) and the bending angles of the FPC 2 at the bending positions 242 are appropriately set according to the shape of the inner surface of the front surface lens 71. For example, if the front surface lens 71 is curved to form the FPC 2 in a curved shape as a whole, the distance between the bending positions 242 is reduced for a part with a small radius of curvature, and the bending amount is increased.

As described, the distances between the bending positions 242 (rows of slit holes 201) and the bending angles can be appropriately set to make the distances between the LEDs 111 and the front surface lens 71 and the emission directions of light of the LEDs 111 all the same. Therefore, the configuration can prevent or suppress the distribution of the strength of light of the illumination apparatus 75 as a DRL light source from becoming nonuniform in front view of the illumination apparatus 75.

In this way, according to the first embodiment, the directions of the optical axes L of the LEDs 111 can be all the same by forming the rows of slit holes 201 at the bending positions 242 of the FPC 2 and bending the FPC 2 at the bending positions 242. The distances (dimensions of the planar portions 241 in the longitudinal direction) between the bending positions 242 (rows of slit holes 201) can be appropriately set to make the distances between the LEDs ill and the front surface lens 71 all the same. Therefore, an illumination apparatus 75 with a uniform light intensity distribution can be obtained. Furthermore, the heat generated by the LEDs 111 can be radiated through the first metal sheet 211 included in the FPC 2. Therefore, the efficiency of cooling the LEDs 111 can be improved. It is only necessary that the distances between the LEDs 111 and the front surface lens 71 are substantially the same, and the distances may not be strictly the same. Similarly, it is only necessary that the directions of the optical axes of the LEDs 111 are substantially parallel, and the directions may not be strictly parallel.

In the configuration shown in FIG. 11, both ends of the flexible circuit board 1 in the longitudinal direction are attached and fixed to the supporting member 751 by the screws 753 as an example of attachment members. The part (part other than the parts fixed by the screws 753) formed in a step shape (three-dimensional shape) between the ends is held in a bent step shape due to the rigidity after the plastic deformation of the first metal sheet 211. The light emission directions of the mounted LEDs 111 are fixed and held. Therefore, the back surface of the flexible circuit board 1 that is flexible (opposite surface of the surface where the LEDs 111 are mounted) may not be closely attached to and supported by the supporting member 751, including the positions where the LEDs 111 are mounted. However, the step-shaped back surface of the flexible circuit board 1 may be designed to be engaged with the shape of the flexible circuit board 1 after bending so that the back surface is abutted with the supporting surface 752 of the supporting member 751. In this way, according to the configuration in which the illumination apparatus 75 (electronic apparatus) includes the FPC 2 of the first embodiment, the shape of the supporting surface 752 of the supporting member 751 may not be formed in a shape conforming to the step shape of the flexible circuit board 1.

Furthermore, according to the configuration, the directions of the optical axes of the LEDs 111 disposed or mounted on the planar portions 241 of the bent FPC 2 (flexible circuit board 1) can be determined and fixed to desired directions relative to the supporting surface 752 of the supporting member 751. The directions can be determined by appropriately setting the dimensions of the planar portions 241, the positions of the slits, and the angles of the mountain folds and the valley folds. Appropriately setting them can properly attain the functions of the mounted electronic components, and the illumination apparatus 75 (electronic apparatus) can have proper functions. As for the connection of the LEDs 111, a parallel connection is also within the scope of the present invention.

The configuration of applying the LEDs as the electronic components has been illustrated, including the examples of the first to third electronic apparatuses. In this way, when the mounted electronic components have a function of directionality, the FPC 2 (flexible circuit board 1) according to the first embodiment can be bent at the bending positions 242 specified by the rows of the slit holes 201 to create an electronic apparatus that can hold a shape to face a direction that effectively attains the function.

The electronic component with the function of directionality is not limited to the surface-mount LED that generates light with directionality or to the mount-type camera module with directionality in the light receiving angle. For example, an infrared light receiving module, a small microphone, a small speaker, a chip type antenna, and the like are also electronic components with the function of directionality. The FPC 2 according to the first embodiment can be suitably used as an FPC on which the electronic components are mounted.

### Second Embodiment

A second embodiment will be described. Configurations common to the first embodiment are provided with the same reference numerals, and the description will not be repeated. In the second embodiment, an illumination apparatus will be illustrated as an example of the electronic apparatus.

### <<Flexible Circuit Board and Illumination Apparatus for Vehicle Lamp>>

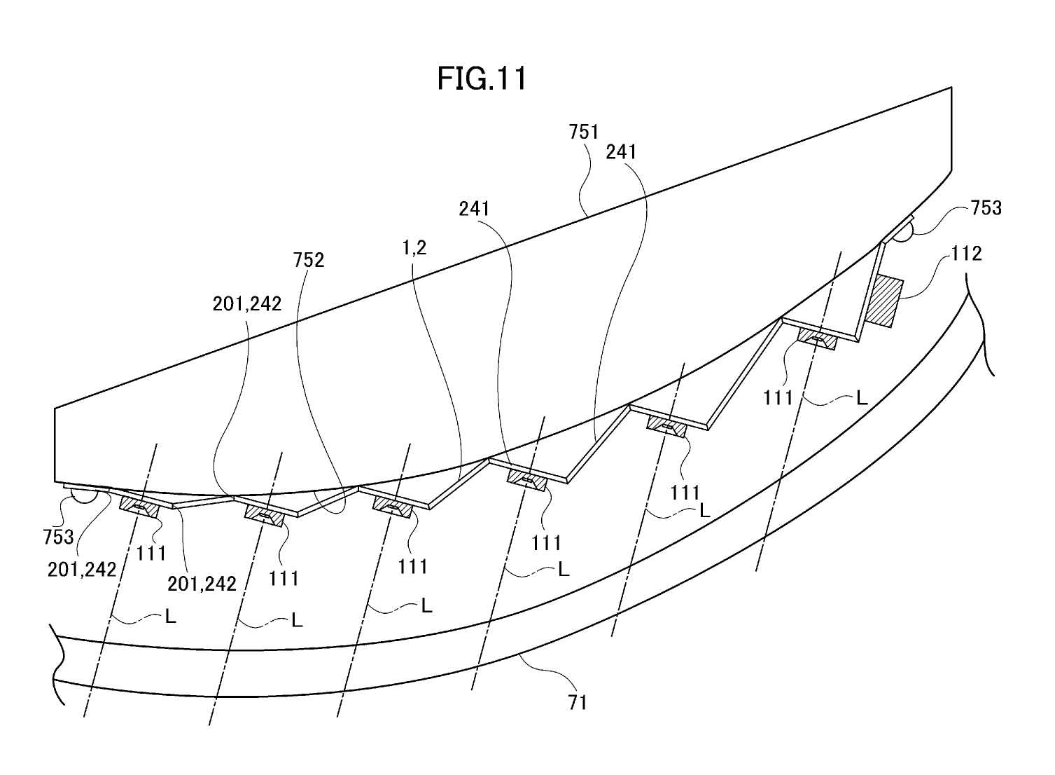

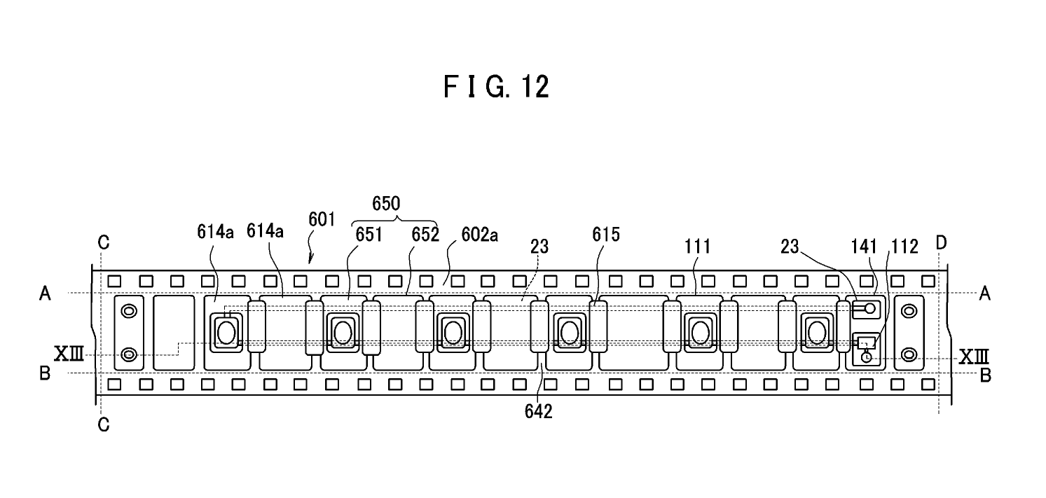

An FPC 602a (flexible printed wiring board) according to the second embodiment is characterized by a metal support cover film 614a used as a cover layer for protecting the conductor pattern 23. Configuration examples of the FPC 602a according to the second embodiment and a flexible circuit board 601 provided with the FPC 602a will be described with reference to FIGS. 12 and 13. FIG. 12 is a flat-surface schematic view showing a configuration example of the flexible circuit board 601 provided with the FPC 602a. FIG. 13 is a sectional schematic view showing a configuration example of the flexible circuit board 601 provided with the FPC 602a and is a sectional view of a XIII-XIII line of FIG. 12. FIGS. 12 and 13 show a state of a planar shape before the FPC 602a (flexible circuit board 601) is formed in a three-dimensional shape. FIG. 12 shows the flexible circuit board 601 in a state that desired electronic components 11, such as the LEDs 111 and the constant-current regulator 112, are mounted on the FPC 602a manufactured by the roll-to-roll process.

As shown in FIGS. 12 and 13, a plurality of LED-mount planar portions 651 and a plurality of connection planar portions 652 are formed on the FPC 602a by a metal support cover film 614a. The LED-mount planar portions 651 are parts on which the LEDs 111 are mounted. The connection planar portions 652 are parts on which the LEDs 111 are not mounted. The LED-mount planar portions 651 and the connection planar portions 652 are alternately arranged in the longitudinal direction of the FPC 602a. Bending portions 642 are further provided between the LED-mount planar portions 651 and the adjacent connection planar portions 652. The bending portions 642 are formed in an elongated band shape extending in the short direction of the FPC 602a. For the convenience of the description, the LED-mount planar portions 651 and the connection planar portions 652 may be collectively called planar portions 650. The planar portions 650 are parts equivalent to the planar portions 241 in the first embodiment and are parts held in a planar shape in a state that the FPC 602a (flexible circuit board 601) is formed in a three-dimensional shape. The bending portions 642 are parts equivalent to the bending positions 242 in the first embodiment and are parts bent when the FPC 602a (flexible circuit board 601) is formed in a three-dimensional shape. In this way, the bending portions 642 are provided at boundaries between the planar portions 650.

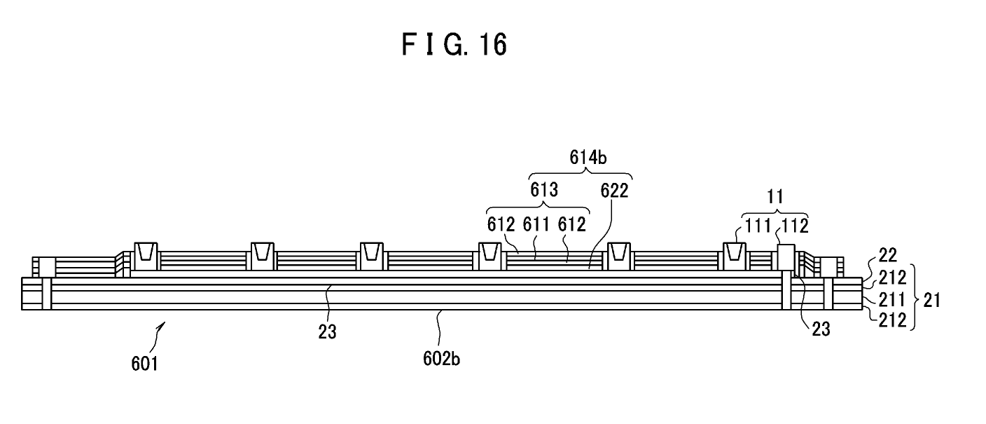

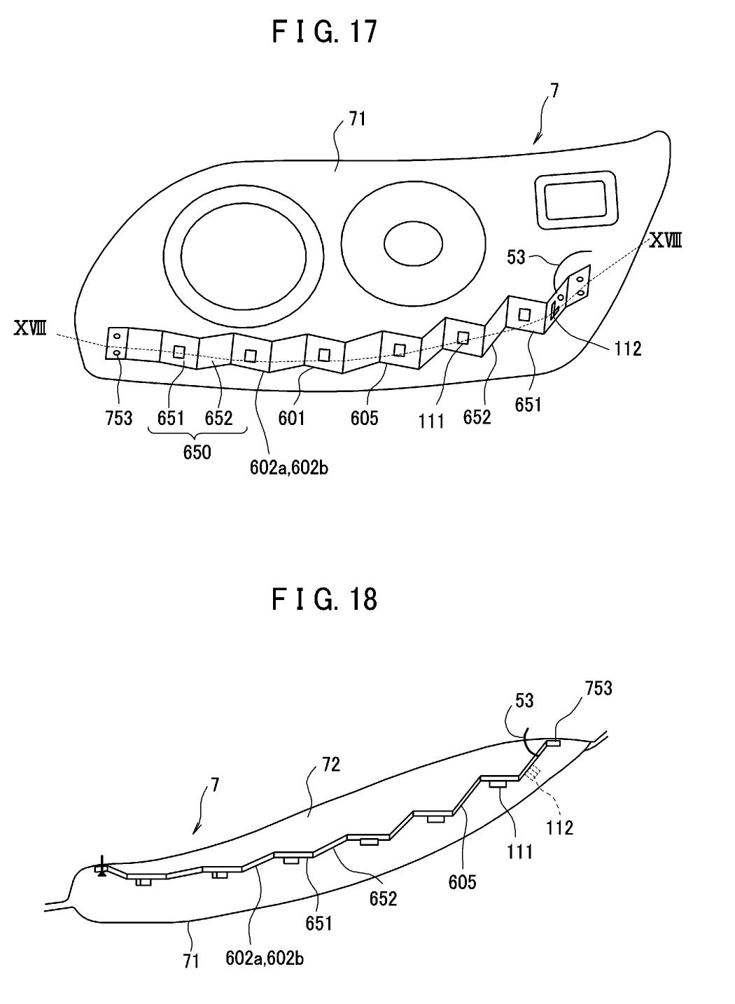

The power feeding cable 53 (not illustrated in FIGS. 12 and 13, see FIGS. 17 and 18) for feeding power from the outside is connected to a power feeding terminal 141 of the FPC 602a. The constant-current regulator 112 is connected to the conductor pattern 23 continued to the power feeding terminal 141 of the FPC 602a, and the plurality of LEDs 111 are connected in series. The conductor pattern 23 is longitudinally wired across the LED-mount planar portions 651, the connection planar portions 652, and the bending portions 642 provided between them so as to connect all of the mounted LEDs 111 (six LEDs 111 in FIG. 12) in series. The flexible circuit board 601 is cut at cutting lines A-A, B-B, C-C, and D-D and separated into pieces (fragments).

As shown in FIG. 13, the FPC 602a has a laminate structure of the base film 21, the first adhesive layer 22, and the conductor pattern 23, as in the FPC 2 of the first embodiment (see FIG. 2). The FPC 602a according to the second embodiment is characterized by the metal support cover film 614a and a resin cover coat (solder resist 615 here) used as cover layers that cover the conductor pattern 23. The configuration of the metal support cover film 614a is similar to the base film 21. Specifically, for example, the metal support cover film 614a has a laminate structure of a metal supporting film 613 and a second adhesive layer 622 provided on one of the surfaces of the metal supporting film 613. The metal supporting film 613 has a laminate structure of a second metal sheet 611 and insulating films 612 covering both surfaces of the second metal sheet 611. The second metal sheet 611 is, for example, aluminum foil of 15 to 50 μm in thickness. It is preferable that the same type of metal as the first metal sheet 211 is applied as the second metal sheet 611. The insulating films 612 are, for example, polyimide resin films (organic insulating films) of about 4 μm in thickness. The manufacturing method of the metal support cover film 614a is, for example, as follows. First, both surfaces of the aluminum foil as an example of the second metal sheet 611 are covered by the insulating films 612 made of a polyimide resin with a thickness of about 4 μm to manufacture the metal supporting film 613. Next, the second adhesive layer 622 for bonding to the FPC 602a is applied to one of the surfaces of the metal supporting film 613 to bake the applied second adhesive layer 622 to form a semi-cured state. In this way, the metal support cover film 614a is manufactured.

In the second embodiment, the metal support cover film 614a is cut in advance with a die corresponding to the planar portions 650 (LED-mount planar portions 651 and connection planar portions 652) and is bonded by thermo-compression bonding to the FPC 602a so as to cover the upper surface of the conductor pattern 23. The metal support cover film 614a is provided with openings for exposing the conductor pattern 23 at positions where the electronic components 11 (LEDs 111, constant-current regulator 112, and the like), the power feeding terminal 141, and the like are mounted. Subsequently, it is preferable to cover the conductor pattern 23 at the bending portions 642 on which the metal support cover film 614a is not bonded, by the solder resist 615 with flexibility and insulation that is a resin cover coat. According to the configuration, the conductor pattern 23 can be protected from damage by bending. As shown in FIG. 12, it is desirable to form the solder resist 615, which is an example of the resin cover coat of the cover layer, across the LED-mount planar portions 651 and the connection planar portions 652 provided on both sides of the bending portions 642 (so that part of the solder resist 615 overlaps part of the metal support cover film 614a at the LED-mount planar portions 651 and the connection planar portions 652).

The rigidity of the bending portions 642 formed as described above is lower than that of the LED-mount planar portions 651 and the connection planar portions 652, and the bending portions 642 can be easily bent. The flexible circuit board 601 is bent in valley folds or mountain folds at the bending portions 642 and formed into a step-like three-dimensional shape. It is preferable to take into account the physical property, the bending angle, and the like of the second metal sheet 611 to determine the width dimension of the bending margin as well as the radius of curvature of the valley fold and the mountain fold of the bending portions 642.

It is preferable that the two adhesive layers (first adhesive layer 22 and second adhesive layer 622) and the insulating films 212 are as thin as possible at the bending portions 642 of the FPC 602a. Such a configuration facilitates the plastic deformation according to the bending of the first metal sheet 211 of the base film 21. In the second embodiment, aluminum foil of 30 to 400 μm in thickness is applied as the first metal sheet 211 of the base film 21, and aluminum foil of 15 to 50 μm in thickness is applied as the second metal sheet 611 of the metal supporting film 613. The positions and the dimensions of the parts corresponding to the planar portions 650 (LED-mount planar portions 651 and connection planar portions 652), the positions of the bending portions 642, and the like of the metal support cover film 614a are designed in advance according to the configuration of an illumination apparatus 605 described later. In the FPC 602a according to the second embodiment, the slit holes 201 for reducing the bending resistance to assist bending may not be formed on the bending portions 642.

Copper foil of 12 to 35 μm in thickness is applied as the conductor foil 24 for forming the conductor pattern 23. It is preferable that the thickness of the first adhesive layer 22 applied to the base film 21 is about 25 μm and that the thickness of the second adhesive layer 622 is about 40 μm. The second adhesive layer 622 can be an adhesive with high thermal conductivity (for example, #TSA series of Toray Industries, Inc.). The solder resist 615 as an example of the resin cover coat of the cover layer for protecting the conductor pattern 23 of the bending portions 642 to be bent can be, for example, product name “NPR80 ID60” of Nippon Polytech Corp. that is a photosensitive solder resist for FPC.

The flexible circuit board 601 is manufactured by mounting the LEDs 111, which are surface-mount LEDs, and the constant-current regulator on the FPC 602a (see FIGS. 12 and 13). The flexible circuit board 601 is bent in valley folds or mountain folds at the bending portions 642 to form a step-like three-dimensional shape.

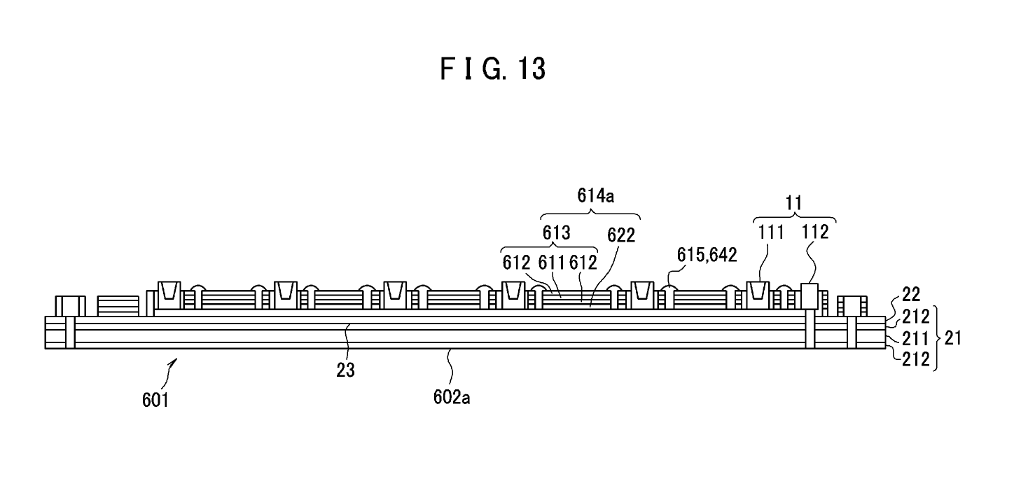

FIG. 14 is a sectional view in which the bent flexible circuit board 601 is cut at a part where the conductor pattern 23 for connecting the LEDs 111 in series is provided. The first metal sheet 211 of the base film 21 and the conductor pattern 23 of two lines for connecting the LEDs 111 in series are the only metal layers in the bending portions 642 to be bent. Therefore, the bending property of the bending portions 642 solely depends on the bending property of the first metal sheet 211 of the base film 21. More specifically, the shape after bending the FPC 602a (flexible circuit board 601) is governed by the characteristics of the first metal sheet 211 of the base film 21. Therefore, the characteristics of the first metal sheet 211 can be set to easily bend the FPC 602a (flexible circuit board 601).

Meanwhile, in the planar portions 650, the first metal sheet 211 included in the base film 21 and the second metal sheet 611 included in the metal support cover film 614a are bonded by the first adhesive layer 22 and the second adhesive layer 622 across the conductor pattern 23 to form a laminated body. Since the laminate structure with two bonded metal sheets has strong resistance to the bending stress, the planar shape of the LED-mount planar portions 651 and the connection planar portions 652 is strongly held. In this way, the FPC 602a (flexible circuit board 601) has the laminate structure, and the three-dimensional shape (step shape in the second embodiment) formed by bending is held. Therefore, the effect of holding the planar shape of the LED-mount planar portions 651 and the connection planar portions 652 according to the second embodiment is higher than that of a flexible circuit board using an FPC including a metal sheet only in the base film 21 or using an FPC including only an organic substrate.

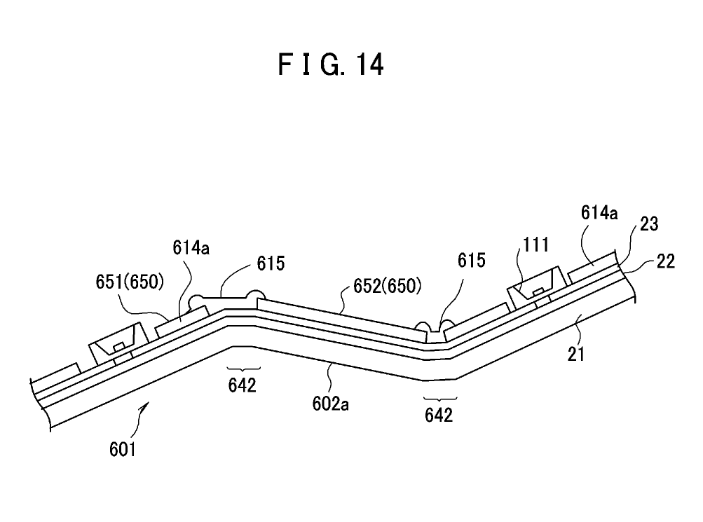

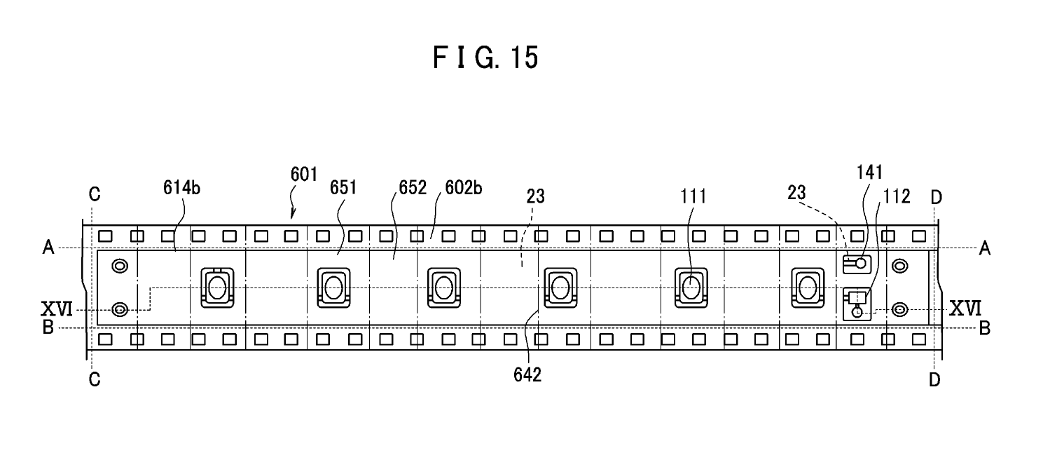

Another example of the second embodiment will be described with reference to FIGS. 15 and 16. FIG. 15 is flat-surface schematic view showing a configuration example of an FPC 602b (flexible printed wiring board) according to another example of the second embodiment. FIG. 16 is a sectional schematic view showing a configuration example of the FPC 602b according to the example of the second embodiment. Compared to the FPC 602a shown in FIGS. 12 and 13, a metal support cover film 614b is not interrupted at the bending portions 642 in the FPC 602b according to the example, and the metal support cover film 614b is provided to integrally continue across the LED-mount planar portions 651, the connection planar portions 652, and the bending portions 642. However, as in the FPC 602a, the metal support cover film 614b includes openings for exposing the conductor pattern 23 at positions of the electronic components 11 (LEDs 111, constant-current regulator 112, and the like), the power feeding terminal 141, and the like mounted later. In the FPC 602b according to the example, the positions of the LED-mount planar portions 651, the connection planar portions 652, the bending portions 642, and the like are conceptual positions in the design. Therefore, the positions of the bending portions 642 are figured out by another method in the FPC 602a of the example. FIG. 15 illustrates a configuration in which the LED-mount planar portions 651, the connection planar portions 652, and the bending portions 642 are covered by the integrally continuous metal support cover film 614b.

In the example, two metal sheets included in the base film 21 and the metal support cover film 614b are closely attached in the first adhesive layer 22 and the second adhesive layer 622 across the conductor pattern 23 to form a laminated body. The laminated body has a function of holding the planar shape of the entire pieces (fragments) of the FPC 602a surrounded by A-A, B-B, C-C, and D-D of FIG. 15, for example. Particularly, unlike the FPC 602a, the metal support cover film 614b is provided to integrally continue across the plurality of LED-mount planar portions 651 and the connection planar portions 652 provided in the pieces (fragments). Therefore, to form a step-like three-dimensional shape, it is preferable to increase the radius of curvature at the bending portions 642 and to form openings (slit holes 201) penetrating the base film 21 at the bending portions 642 as in the first embodiment (see FIGS. 3 to 5). Although it is desirable that the second metal sheet 611 is thin in order to reduce the radius of curvature, it is suitable that the second metal sheet 611 is aluminum foil of 10 to 35 μm in thickness from the viewpoint of mechanical strength and processability.

According to the second embodiment, other members for holding the FPC 602a or 602b (flexible circuit board 601) in a three-dimensional shape may not be added. Therefore, an increase in the number of components and an increase in the assembly man-hours can be suppressed. Resistance to repeated bending is not required for the bending portions 642. The bending portions 642 have a configuration in which bending is easy after manufacturing of the FPC 602a or 602b, and the three-dimensional shape after the bending can be held. In the FPCs 602a and 602b according to the second embodiment, the base film 21 including the first metal sheet 211 and the metal support cover films 614a and 614b including the second metal sheet 611 can be easily manufactured. In the illumination apparatus 605 according to the second embodiment, the base film 21 supporting the conductor pattern 23 that tends to be hot and the metal support cover films 614a and 614b covering the conductor pattern 23 are metal sheets. Therefore, the heat radiation is excellent. Although the configuration in which the plurality of LEDs 111 are arranged and mounted in a line in the longitudinal direction is illustrated in FIGS. 12 and 13, the LEDs 111 may be obviously disposed in a plurality of lines. A plurality of LEDs 111 may be mounted on one LED-mount planar portion 651. The number of rows of the LEDs 111 and the number of LEDs 111 mounted on one LED-mount planar portion 651 can be easily changed. Although a flexible member is used for the base film 21 of the FPCs 602a and 602b according to the second embodiment, the LED-mount planar portion 651 has a laminate structure of two metal sheets with low elasticity (first metal sheet 211 and second metal sheet 611) and an insulating film. Therefore, the flexibility is suppressed, and the rigidity is high.

As described, the slit holes 201 as in the first embodiment may not be formed on the bending portions 642 of the base film 621 of the FPC 602a according to the second embodiment. However, it is preferable to provide the slit holes 201 on the bending portions 642 of the base film 21 of the FPCs 602a and 602b of the second embodiment to facilitate bending. Particularly, it is effective when the thickness of the aluminum foil applied as the first metal sheet 211 of the base film 21 is 150 μm or more. Elongated slit holes or a plurality of aligned slit holes can be provided along ridgelines of the valley folds and the mountain folds of the bending portions 642 to reduce the radius of curvature in bending and to facilitate bending. The slit holes 201 may not penetrate the first metal sheet 211, and a groove shape formed by cutting one of the surfaces is also effective.

The illumination apparatus 605 as an example of the electronic apparatus according to the second embodiment will be described with reference to FIGS. 17 and 18. FIG. 17 is a front-surface schematic view showing a configuration example of the illumination apparatus 605 and the vehicle lamp 7 (headlamp) as an application example of the illumination apparatus 605. FIG. 18 is a sectional view of a XVIII-XVIII line of FIG. 17. An example of a configuration of applying the illumination apparatus 605 to a daytime running lamp (DRL) of the vehicle lamp 7 will be illustrated. The functions and the characteristics of the illumination apparatus 605 mounted on the vehicle lamp 7 are the same as those of the third illumination apparatus 75 in the first embodiment. The optical axis directions of the LEDs 111 and the positional relationship with the front surface lens 71 are also the same as in the first embodiment.

The illumination apparatus 605 includes the flexible circuit board 601 in which the plurality of LEDs 111 are mounted on the FPC 602a or 602b in an elongated band shape. The plurality of LEDs 111 are mounted on the LED-mount planar portions 651 provided on the FPC 602a or 602b. As described, since the plurality of LED-mount planar portions 651 are provided in the longitudinal direction of the FPC 602a or 602b, the plurality of LEDs 111 are arranged in the longitudinal direction of the FPC 602a or 602b. The plurality of LED-mount planar portions 651 provided with the LEDs 111 and the plurality of connection planar portions 652 not provided with the LEDs 111 are alternately arranged in the longitudinal direction, and the bending portions 642 between the LED-mount planar portions 651 and the connection planar portions 652 are alternately bent in mountain folds and valley folds. In this way, the FPC 602a or 602b is formed in a step shape as a whole. More specifically, the connection planar portions 652 arranged between the LED-mount planar portions 651 provided with the LEDs 111 connect the LED-mount planar portions 651 in a step shape so that the LED-mount planar portions 651 are parallel to each other.

In FIG. 17, the illumination apparatus 605 is arranged on the vehicle lamp 7 (headlamp) in the direction in which the FPC 602a or 602b extends in the horizontal direction. As in the first embodiment, distances between the LEDs 111 and the front surface lens 71 are all the same, and the optical axes L of the LEDs 111 are all parallel (see FIG. 11). The front surface lens 71 of the vehicle lamp 7 is formed in, for example, an inclined surface or a curved surface according to the vehicle body shape or the like. Therefore, the FPC 602a or 602b of the illumination apparatus 605 is bent in mountain folds or valley folds at the bending portions 642 so that the FPC 602a or 602b as a whole is in a curved shape conforming to the shape of the front surface lens 71.

The power feeding cable 53 is attached to the power feeding terminal 141. Attachment mechanisms, such as the screws 753, are used to fix both ends of the FPC 602a or 602b in the longitudinal direction to predetermined positions of the vehicle lamp 7. When power is fed from the outside in this state, the flexible circuit board 601 functions as the illumination apparatus 605. The configuration can provide an electronic apparatus including: the FPC 602a or 602b that can be easily formed in a three-dimensional shape and that has excellent heat radiation; the flexible circuit board 601; the illumination apparatus 605 with excellent design provided with the flexible circuit board; and the like.

Although various embodiments of the present invention have been described in detail with reference to the drawings, the embodiments just illustrate specific examples for carrying out the present invention. The technical scope of the present invention is not limited to the embodiments. Various changes can be made in the present invention without departing from the scope of the present invention, and the changes are also included in the technical scope of the present invention.

For example, the material and the dimension of the base film illustrated in the embodiments are examples, and the material and the dimension are not limited to the ones described above. Although semiconductor elements and the like can be mounted on the FPC based on the TAB system in the embodiments, the mounting system of the semiconductor elements is not limited. Other than the TAB system, a COF system is also possible. Although the left vehicle lamp (headlamp) has been illustrated as an illumination apparatus in the embodiments, a right vehicle lamp with a symmetric configuration can also be manufactured.

The present invention is a technique effective for a flexible wiring board, a flexible circuit board, and an electronic apparatus. According to the present invention, a three-dimensional shape of a flexible circuit board can be easily and certainly formed and held without using a plate-like member such as a metal material.

What is claimed is:

1. A flexible printed wiring board comprising: a base film including a first metal sheet; a first adhesive layer laminated on one of surfaces of the base film; a conductor pattern bonded by the first adhesive layer; and a cover layer that covers the conductor pattern, wherein
a plurality of planar portions held in a planar shape and bending portions provided between the planar portions are arranged in a longitudinal direction,
the cover layer provided to the planar portions includes a second metal sheet and a second adhesive layer, and
the cover layer provided to the bending portions includes a resin cover coat.

2. The flexible printed wiring board according to claim 1, wherein
the second metal sheet is made of aluminum foil of 15 to 50 μm in thickness.

3. The flexible printed wiring board according to claim 1, wherein
the planar portions include two planar portions which are an LED-mount planar portion provided with an LED and a connection planar portion not provided with an LED, and the bending portions are connected and arranged in the longitudinal direction between the two planar portions.

4. The flexible printed wiring board according to claim 1, wherein
both surfaces of at least one of the first metal sheet and the second metal sheet are covered by organic insulating films including a polyimide resin of 4 μm in thickness.

5. The flexible printed wiring board according to claim 1, wherein
the first metal sheet is made of aluminum foil of 30 to 400 μm in thickness.

6. The flexible printed wiring board according to claim 1, wherein
slit holes are formed side by side at the bending portions of the first metal sheet.

7. A flexible printed wiring board comprising: a base film including a first metal sheet; a first adhesive layer laminated on one of surfaces of the base film; a conductor pattern bonded by the first adhesive layer; and a cover layer that covers the conductor pattern, wherein
a plurality of planar portions held in a planar shape and bending portions provided between the planar portions are arranged in a longitudinal direction, and
the cover layer comprises: a second metal sheet integrally continued across the planar portions and the bending portions; and a second adhesive layer.

8. The flexible printed wiring board according to claim 7, wherein
the second metal sheet is made of aluminum foil of 10 to 35 μm in thickness.

9. The flexible printed wiring board according to claim 7, wherein
the planar portions include two planar portions which are an LED-mount planar portion provided with an LED and a connection planar portion not provided with an LED, and the bending portions are connected and arranged in the longitudinal direction between the two planar portions.

10. The flexible printed wiring board according to claim 7, wherein
both surfaces of at least one of the first metal sheet and the second metal sheet are covered by organic insulating films including a polyimide resin of 4 μm in thickness.

11. The flexible printed wiring board according to claim 7, wherein
the first metal sheet is made of aluminum foil of 30 to 400 μm in thickness.

12. The flexible printed wiring board according to claim 7, wherein
slit holes are formed side by side at the bending portions of the first metal sheet.

13. A flexible circuit board including a flexible printed wiring board,
the flexible printed wiring board comprising:
a base film including a first metal sheet; a first adhesive layer laminated on one of surfaces of the base film; a conductor pattern bonded by the first adhesive layer; and a cover layer that covers the conductor pattern, wherein
a plurality of planar portions held in a planar shape and bending portions provided between the planar portions are arranged in a longitudinal direction,
the cover layer provided to the planar portions includes a second metal sheet and a second adhesive layer,
the cover layer provided to the bending portions includes a resin cover coat,
the planar portions include a plurality of LED-mount planar portions provided with surface-mount LEDs and a connection planar portion not provided with a surface-mount LED, and
mountain folds or valley folds are made at the bending portions, and a step shape is formed by the LED-mount planar portions and the connection planar portion.

14. An electronic apparatus including a flexible circuit board,
the flexible circuit board comprising:
a flexible printed wiring board comprising: a base film including a first metal sheet; a first adhesive layer laminated on one of surfaces of the base film; a conductor pattern bonded by the first adhesive layer; and a cover layer that covers the conductor pattern, wherein
a plurality of planar portions held in a planar shape and bending portions provided between the planar portions are arranged on the flexible printed wiring board in a longitudinal direction,
the cover layer provided to the planar portions includes a second metal sheet and a second adhesive layer,
the cover layer provided to the bending portions includes a resin cover coat,
the planar portions include a plurality of LED-mount planar portions provided with surface-mount LEDs and a connection planar portion not provided with a surface-mount LED,
mountain folds or valley folds are made at the bending portions, a step shape is formed by the LED-mount planar portions and the connection planar portion, and
optical axes of the surface-mount LEDs are parallel.
